(19) United States
(12) Patent Application Publication
(10) Pub. No.: US 2007/0155168 A1
(43) Pub. Date: Jul. 5, 2007

(54) METHOD FOR FORMING A CONDUCTIVE PLUG OF A SEMICONDUCTOR DEVICE

(76) Inventor: Jin Kyu Lee, Gyeonggi-do (KR)

Correspondence Address: SHERR & NOURSE, PLLC, 620 HERNDON PARKWAY, SUITE 200, HERNDON, VA, 20170, US

(21) Appl. No.: 11/615,756

(22) Filed: Dec. 22, 2006

(30) Foreign Application Priority Data
Dec. 29, 2005 (KR) 10-2005-0134061

(51) Int. Cl. H01L 21/4763

(52) U.S. Cl. 438/633; 438/692; 438/637

(57) ABSTRACT

Embodiments relate to a method for forming a conductive plug of a semiconductor device that may include preparing a semiconductor substrate having multilayer metal interconnections, forming interlayer insulating layers above the semiconductor substrate, etching part of each interlayer insulating layer such that each multilayer metal connection is exposed, and forming a via hole, depositing a conductive layer such that the via hole is filled, and performing chemical mechanical polishing (CMP) on the conductive layer such that each interlayer insulating layer is exposed, and forming the plug. The step of performing the CMP on the conductive layer may be performed using a polishing pad having a polishing speed of about 3200 angstroms/min to about 5000 angstroms/min.

The present application claims priority under 35 U.S.C. 119 and 35 U.S.C. 365 to Korean Patent Application No. 10-2005-0134061 (filed on Dec. 29, 2005), which is hereby incorporated by reference in its entirety.

### BACKGROUND

As semiconductor devices have become more highly integrated, technology for forming a multilayer interconnection may become more important. To vertically and electrically connect multilayer metal interconnections, technology for forming a conductive plug may also be important. A conductive plug may be made of tungsten (W), which may have excellent conductivity and interlayer filling characteristics.

The conductive plug may be formed by filling a conductive layer such that a contact hole or a via hole may be filled. The filled conductive layer may then be planarized.

A method of planarizing the filled conductive layer may include an etch-back technique and a chemical mechanical polishing (CMP) technique. Hence, the conductive layer may be planarized by a CMP technique. A thickness and CMP conditions of the conductive layer may be varied according to each level (or each layer).

Further, the conductive plug may have different integration densities according to a stacked level. In other words, the conductive plug connecting a semiconductor substrate and a primary interconnection may have a very high integration density. For a conductive plug connecting neighboring upper interconnections, the higher the metal interconnection goes, the lower the integration density becomes, as in the purpose of the multilayer metal interconnection. This means that the conductive plug connecting the upper interconnections may connect with several metal interconnections, and thus may be very important.

The upper conductive plugs connecting the interconnections, particularly, the fifth plug connecting the fourth and fifth metal interconnections and the sixth plug connecting the fifth and sixth metal interconnections, may have a pattern-dependent defect. This may be known as a black hole defect, and may occur on their surfaces.

This pattern-dependent defect may cause contact failure with the metal interconnection that may be formed later. Electrical reliability of the semiconductor device may thus be lowered. Moreover, device malfunction may occur.

The pattern-dependent defect may be attributed to pattern density, i.e. integration density, of the plug (as indicated by its name), and may be generated at a portion where the pattern density is relatively low.

The pattern-dependent defect may become more serious on a surface of an edge of the plug, compared to a center of the plug.

Various causes and distributions of the pattern-dependent defect have been identified.

For example, the pattern-dependent defect may occur when a pad for a relatively low polishing speed is used. Such a pad may be, for example, a Rodel pad. In this example, the use of the pad having a low polishing speed may make a CMP time longer.

For this reason, a plug of a low-integration-density portion, where the interlayer insulating layer is exposed relatively quickly, may undergo a CMP for a longer time than the plug of a high-integration-density portion. The above-described defect may therefore occur. Here, as well known as the micro-loading effect, the low-integration-density portion may have relatively fast etching and polishing speeds as compared to the high-integration-density portion.

Because the Rodel pad may have a relatively low polishing speed (3000 angstroms or less per minute), a corresponding CMP process may give rise to the pattern-dependent defect, i.e. the black hole defect.

The portion where the integration density is relatively low may be an isolation region. When the isolation region and the pattern dense area (e.g. the cell region) are subjected to the CMP at the same time, a conductive plug may first be formed on the isolation region.

Further, the Rodel pad may have a porous structure in order to increase a chemical reaction effect between slurry and a wafer, and thus may have relatively small pores, each of which may have a size of about 50 μm to about 120 μm.

However, because the Rodel pad may have a plurality of pores, it may have low absorbing efficiency of the slurry. Hence, a large quantity of slurry and a large quantity of chemical may be required. If the CMP process is performed for a long time under the conditions where a relatively large quantity of slurry and chemical are required, the conductive plug (formed on the low integration density portion) at which the interlayer insulating layer is relatively fast exposed may be more quickly lost.

Moreover, a pattern-dependent defect may cause a top surface of the conductive plug to be dented.

If denting occurs, the dented portion may allow residues such as slurry particles, tungsten materials, and oxide materials generated during the polishing process to be left behind. This may be responsible for an increase of contact resistance and contact failure during subsequent metallization processes.

In addition, the pattern-dependent defect may occur because an edge portion of the via hole may have a conductive layer deposited to be less than the center of the via hole. Furthermore, during the CMP process, the edge may have a polishing speed faster than that of the center, and thus may be oxidized relatively faster. Hence, a pattern-dependent defect may occur.

### SUMMARY

Embodiments relate to a method for forming a conductive plug of a semiconductor device.

Embodiments relate to a method for forming a conductive plug of a semiconductor device that may be capable of preventing pattern-dependent defect on a surface of the conductive plug that may be formed at a portion having relatively low integration density.

Embodiments relate to a method for forming a conductive plug of a semiconductor device that may be capable of preventing a so-called black hole defect occurring on the surface of a tungsten plug during a chemical mechanical polishing (CMP) process for forming the tungsten plug connecting between upper interconnections.

According to embodiments, a method for forming a conductive plug of a semiconductor device may include preparing a semiconductor substrate having multilayer metal interconnections, forming interlayer insulating layers above the semiconductor substrate, etching part of each interlayer insulating layer such that each multilayer metal connection is exposed, and forming a via hole, depositing a conductive layer such that the via hole is filled, and performing chemical mechanical polishing (CMP) on the conductive layer such that each interlayer insulating layer is exposed, and forming the plug. The step of performing the CMP on the conductive layer may be performed using a polishing pad having a polishing speed of about 3200 angstroms/min to about 5000 angstroms/min.

According to embodiments, a method for forming a conductive plug of a semiconductor device may include preparing a semiconductor substrate having multilayer metal interconnections, forming interlayer insulating layers above the semiconductor substrate, etching part of each interlayer insulating layer such that each multilayer metal connection is exposed, and forming a via hole, depositing a conductive layer such that the via hole is filled, performing chemical mechanical polishing (CMP) on the conductive layer such that each interlayer insulating layer is exposed, and forming the plug, and cleaning a surface of the plug. The step of cleaning the surface of the plug includes the sub-steps of: removing primary residues from the surface of the plug, removing oxide components from the surface of the plug, and removing secondary residues from the surface of the plug.

### BRIEF DESCRIPTION OF THE DRAWINGS

FIGS. 1 and 2 are example sectional diagrams illustrating a conductive plug of a semiconductor device and a method for forming a conductive plug of a semiconductor device according to embodiments.

### DETAILED DESCRIPTION OF EMBODIMENTS

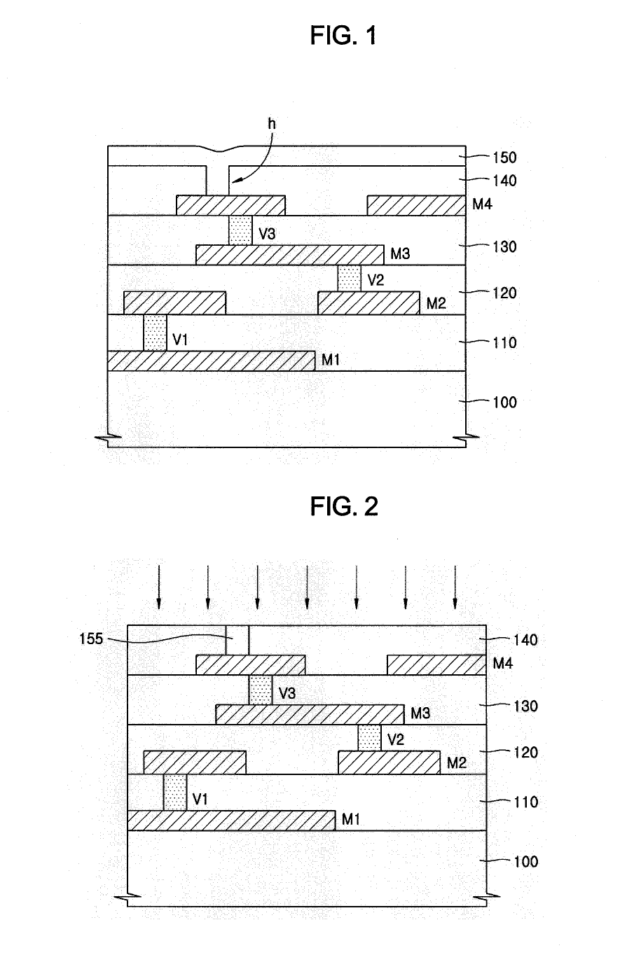

Referring to FIG. 1, semiconductor substrate 100 having multilayer metal interconnections M1 to M4 may be prepared.

Although not illustrated in the drawings, semiconductor substrate 100 may include metal oxide semiconductor (MOS) transistors, and the metal interconnections may be connected with gates of the MOS transistors.

According to embodiments, first, second, third, and fourth metal interconnections M1, M2, M3, and M4 may be formed. The multilayer metal interconnections M1 to M4 may be insulated by interlayer insulating layers 110, 120 and 130, each of which may be interposed between the two neighboring metal interconnections.

Further, first metal interconnection M1 may be electrically connected with second metal interconnection M2 using first plug V1. Second metal interconnection M2 may be electrically connected with third metal interconnection M3 using second plug V2. Third metal interconnection M3 may be electrically connected with fourth metal interconnection M4 using third plug V3.

Interlayer insulating layer 140 may be deposited on the result of semiconductor substrate 100 having fourth metal interconnection M4. Interlayer insulating layer 140 may be etched such that fourth metal interconnection M4 is exposed. This may form via hole h.

Tungsten metal layer 150 may be deposited having a prescribed thickness such that the via hole h may be filled.

Referring to FIG. 2, a chemical mechanical polishing (CMP) process may be carried out such that the tungsten metal layer 150 may be filled in the via hole h, thereby forming a fourth tungsten plug 155.

In embodiments, the CMP process may be carried out using a pad having a polishing speed of 3200 angstroms or more per minute. In embodiments, the polishing speed may be 3200 angstroms per minute to 5000 angstroms per minute. Such conditions may include a TWI pad.

As described above, when the pad having a relatively high polishing speed is used, an overall processing time may be reduced by 20 seconds or more. Thus, although the conductive plug of an isolation region may be exposed relatively quickly, the time when the conductive plug is exposed to slurry may be reduced. Thus, a pattern-dependent defect may be reduced.

Further, although the center of the plug may have a thickness partially different from a thickness of an edge of the plug, and although the polishing speed of the edge of the plug may be relatively fast, the overall polishing speed may be improved, so that differences between the thicknesses and between polishing uniformities may not exert a great influence on the pattern-dependent defect.

In addition, the TWI pad may be relatively large, and may have a pore size of about 80 μm to about 120 μm. Moreover it may have a internal structure of a fabric. In this manner, when the inside of the pad has the relatively large pore size and the fabric structure, the TWI pad may have slurry absorptance higher than a related art Rodel pad. Hence, a supplied quantity of chemical may be reduced. Accordingly, thus defects that may be caused by a large quantity of slurry and chemical may be prevented.

As described above, after fourth tungsten plug 155 may be formed, a cleaning process may be performed to remove impurities that may be occur on a surface of fourth tungsten plug 155.

According to embodiments, the cleaning process may include removing primary residues such as metal residues or slurry residues. The process may also include removing oxide components, and removing secondary residues. Accordingly, the process may be able to remove all metal residues, slurry residues, and parasite oxide components that may occur on the surface of fourth tungsten plug 155.

In embodiments, the step of removing the residues may be accomplished by the cleaning process using a solution of NH₄OH, and the step of removing the oxide components may be accomplished by the cleaning process using a solution of HF.

In embodiments, all of the residues, including the oxide components occurring on the surface of fourth tungsten plug 155, may be removed by the NH₄OH/HF/NH₄OH cleaning processes. This may prevent the occurrence of the black hole defect and the contact failure.

It should be understood that embodiments are not limited to the above described process.

For example, in embodiments, any pad may be used if its polishing speed and internal structure are adequate. In embodiments, any pad having a polishing speed of more than approximately 3200 angstroms/min with an internal fabric structure may be used.

Further, although the cleaning process of this embodiment may be carried out by the three steps (e.g. the residue removing step, the oxide component removing step, and the residue removing step), other cleaning processes could be used. For example, in embodiments only the residue removing step and the oxide component removing step may be used. Furthermore, the cleaning process may be applied to all the conductive plugs including the fourth conductive plug.

In embodiments, any material may be used for the plug material in place of tungsten, so long as it has adequate conductivity and interlayer filling characteristics.

Moreover, in embodiments this process may be used on any plug in addition to the fourth plug, so long as it can connect the upper metal interconnections more than the fourth metal interconnection.

In embodiments, this process may be used on any low density region in addition to the isolation region. For example, the low integration density region may include a core and its surrounding circuit of the semiconductor device other than the isolation region.

In embodiments, when the via plug connecting between the metal interconnections, for example between the upper metal interconnections (more than the fourth metal interconnection), may be formed, the CMP process may be performed using the polishing pad having the polishing speed of 3200 angstroms/min or more, a relatively large pore size, and an internal fabric structure.

According to embodiments, the use of a polishing pad having a relatively fast polishing speed may allow the CMP process to be performed irrespective of the pattern density. Accordingly, it may be possible to prevent the defects from occurring on the surface of the plug within the region, such as the isolation region, where the plugs are sparsely formed. Further, due to the increase of the polishing speed, the polishing difference between the center and the edge of the plug may be reduced.

In embodiments, the use of the polishing pad having a large pore size and a fabric structure may improve the absorptance of slurry. Accordingly, a quantity of supplied chemical and the slurry may be reduced. Hence, a surface defect caused by the slurry may be reduced.

In embodiments, after the conductive plug may be formed, certain residues, including the oxide components, that may occur on the surface of the tungsten plug may be removed by the NH₄OH/HF/NH₄OH cleaning processes. This may further reduce the occurrence of the black hole defect.

It will be apparent to those skilled in the art that various modifications and variations can be made to embodiments. Thus, it is intended that embodiments cover modifications and variations thereof within the scope of the appended claims. It is also understood that when a layer is referred to as being “on” or “over” another layer or substrate, it can be directly on the other layer or substrate, or intervening layers may also be present.

What is claimed is:

1. A method comprising:
forming a conductive layer an over an interlayer insulating layer, the conductive layer filling a via hole formed in the interlayer insulating layer;
performing chemical mechanical polishing (CMP) on the conductive layer to expose the interlayer insulating layer and form the plug,
wherein CMP is performed on the conductive layer using a polishing pad having a polishing speed of at least 3200 angstroms/min.

2. The method of claim 1, wherein performing the CMP on the conductive layer is performed using a polishing pad having a polishing speed of about 3200 angstroms/min to about 5000 angstroms/min.

3. The method of claim 1, further comprising:
preparing a semiconductor substrate having multilayer metal interconnections;
forming an interlayer insulating layer above the semiconductor substrate;
etching part of the interlayer insulating layer such that at least one multilayer metal connection is exposed, and forming the via hole;
depositing the conductive layer over the interlayer insulating layer such that the via hole is filled.

4. The method of claim 1, wherein the polishing pad comprises pores having a diameter of about 80 μm to about 120 μm,

5. The method of claim 4, wherein an internal structure of the polishing pad comprises a fabric.

6. The method of claim 1, wherein the metal interconnection exposed by the via hole is at least a fourth metal interconnection.

7. The method of claim 6, wherein the metal interconnection exposed by the via hole comprises a fourth-layer metal interconnection.

8. The method of claim 1, wherein the conductive layer comprises tungsten.

9. The method of claim 1, further comprising cleaning a surface of the plug after forming the plug.

10. The method of claim 9, wherein cleaning the surface of the plug comprises removing residues from the surface of the plug and removing oxide components from the surface of the plug.

11. The method of claim 10, wherein removing the residues comprises cleaning with a solution of NH₄OH, and removing the oxide components comprises cleaning with a solution of HF.

12. The method of claim 10, further comprising removing residues after removing the oxide components.

13. A method comprising:
preparing a semiconductor substrate having multilayer metal interconnections;
forming at least one interlayer insulating layer above the semiconductor substrate;
etching part of the at least one interlayer insulating layer to form at least one via hole exposing at least one multilayer metal connection;
depositing a conductive layer over the least one interlayer insulating layer such that the at least one via hole is filled;
performing chemical mechanical polishing (CMP) on the conductive layer such that the at least one interlayer insulating layer is exposed to form a plug; and
cleaning a surface of the plug by removing primary residues from the surface of the plug and removing oxide components from the surface of the plug.

14. The method of claim 13, further comprising removing secondary residues from the surface of the plug after removing oxide components from the surface of the plug.

15. The method of claim 14, wherein removing the residues comprises cleaning with a solution of NH₄OH, and removing the oxide components comprises cleaning with a solution of HF.

16. The method of claim 13, wherein the CMP is performed using a polishing pad comprising pores having a diameter of approximately 80 μm to about 120 μm, and wherein an internal structure of the polishing pad comprises fabric.

17. The method of claim 13, wherein performing the CMP on the conductive layer is performed using a polishing pad having a polishing speed of at least 3200 angstroms/min.

18. The method of claim 13, wherein performing the CMP on the conductive layer is performed using a polishing pad having a polishing speed of approximately 3200 angstroms/min to approximately 5000 angstroms/min.

19. The method of claim 13, wherein the metal interconnection exposed by the at least one via hole is at least a fourth metal interconnection.

20. The method of claim 19, wherein the metal interconnection exposed by the via hole comprises a fourth-layer metal interconnection.
